(19) United States
(12) Patent Application Publication
(10) Pub. No.: US 2026/0343979 A1
(43) Pub. Date: Oct. 29, 2026

(54) SEMICONDUCTOR STRUCTURE

(71) Applicant: ENKRIS SEMICONDUCTOR, INC., Suzhou (CN)

(72) Inventors: Liyang ZHANG, Suzhou (CN); Kai CHENG, Suzhou (CN)

(73) Assignee: ENKRIS SEMICONDUCTOR, INC., Suzhou (CN)

(21) Appl. No.: 19/737,321

(22) Filed: Jul. 10, 2026

Related U.S. Application Data
(63) Continuation of application No. 18/352,187, filed on Jul. 13, 2023, now abandoned.

(30) Foreign Application Priority Data
Aug. 26, 2022 (CN) 202211035045.3

(51) Int. Cl. H10D 62/85; H10D 62/815

(52) U.S. Cl. CPC H10D 62/8503; H10D 62/8164

(57) ABSTRACT

A semiconductor structure comprises a substrate; a V-shaped groove layer, a V-shaped groove enlargement layer and a semiconductor epitaxial layer stacked from bottom to top; an insertion layer; and a first V-shaped groove arranged on a surface of the V-shaped groove layer close to the V-shaped groove enlargement layer; a second V-shaped groove arranged on a surface of the V-shaped groove enlargement layer close to the semiconductor epitaxial layer, where a size of the second V-shaped groove is greater than a size of the first V-shaped groove In the present disclosure, a lateral epitaxy effect of the V-shaped groove enlargement layer and the semiconductor epitaxial layer is realized for two times, which makes dislocation fully bend, effectively improving crystal quality.

### CROSS-REFERENCE TO RELATED APPLICATIONS

This application is a continuation of U.S. Patent Application No. 18/352,187, filed on Jul. 13, 2023, which claims priority to Chinese Patent Application No. 202211035045.3, filed on Aug. 26, 2022. All of the aforementioned applications are incorporated herein by reference in their entireties.

### TECHNICAL FIELD

The present disclosure relates to the field of semiconductor technologies, and in particular to a semiconductor structure.

### BACKGROUND

Gallium nitride (GaN), as a wide bandgap semiconductor material, has broad application prospects. With the development and application of GaN-based device technology, the general lighting and light-emitting fields in the world are basically monopolized by GaN-based devices. Currently, conventional substrates such as silicon (Si), silicon carbide (SiC) or sapphire are unable to avoid plenty of defects in GaN-based materials due to heteroepitaxy, which seriously affects the performance and life of GaN-based devices.

### SUMMARY

According to an aspect of the present disclosure, the present disclosure provides a semiconductor structure, including:
a substrate; a V-shaped groove layer, a V-shaped groove enlargement layer and a semiconductor epitaxial layer stacked from bottom to top, where the V-shaped groove enlargement layer is a multi-layer structure;
an insertion layer;
a first V-shaped groove, located on a surface of the V-shaped groove layer close to the V-shaped groove enlargement layer; and
a second V-shaped groove, located on a surface of the V-shaped groove enlargement layer close to the semiconductor epitaxial layer, where a size of the second V-shaped groove is greater than a size of the first V-shaped groove, and the semiconductor epitaxial layer fills the second V-shaped groove and is located on the V-shaped groove enlargement layer.

As an optional embodiment, dislocation defects in the V-shaped groove enlargement layer are bent at the insertion layer.

As an optional embodiment, the insertion layer is located between the V-shaped groove enlargement layer and the semiconductor epitaxial layer.

As an optional embodiment, the insertion layer is located in the semiconductor epitaxial layer.

As an optional embodiment, a surface, facing away from the V-shaped groove enlargement layer, of the insertion layer is a flat surface.

As an optional embodiment, a material of the insertion layer includes one or more of AlN, AlGaN, AlInN and AlInGaN.

As an optional embodiment, a thickness of the V-shaped groove enlargement layer inside the second V-shaped groove is less than a thickness of the V-shaped groove enlargement layer outside the second V-shaped groove in a vertical direction.

As an optional embodiment, an opening width of the first V-shaped groove is less than 200 nm, and an opening width of the second V-shaped groove is greater than 200 nm.

As an optional embodiment, a depth of the first V-shaped groove is less than 200 nm, and a depth of the second V-shaped groove is greater than 200 nm.

As an optional embodiment, a density of the first V-shaped groove and a density of the second V-shaped groove are both greater than 1E9/cm².

As an optional embodiment, a projection of the second V-shaped groove on the substrate corresponds to a projection of the first V-shaped groove on the substrate in a one-to-one relationship.

As an optional embodiment, the V-shaped groove enlargement layer is the multi-layer structure including one or more of AlN, AlGaN, GaN, InGaN and AlInGaN.

As an optional embodiment, the semiconductor structure further includes a second superlattice structure adjacent to and located above the V-shaped groove enlargement layer, where the second superlattice structure includes a third V-shaped groove corresponding to the second V-shaped groove.

As an optional embodiment, an opening width of the third V-shaped groove in the second superlattice structure gradually decreases along a direction from the substrate to the semiconductor epitaxial layer.

As an optional embodiment, an opening depth of the third V-shaped groove in the second superlattice structure gradually decreases along a direction from the substrate to the semiconductor epitaxial layer.

### BRIEF DESCRIPTION OF THE DRAWINGS

FIG. 1 is a schematic structural diagram of a semiconductor structure in accordance with an embodiment of the present disclosure.

FIG. 2 is a partial enlarged view of area A in FIG. 1.

FIG. 3 is another schematic structural diagram of a semiconductor structure in accordance with an embodiment of the present disclosure.

FIG. 4 is a schematic structural diagram of a semiconductor structure in accordance with an embodiment of the present disclosure.

FIG. 5 is a schematic structural diagram of a semiconductor structure in accordance with an embodiment of the present disclosure.

FIG. 6 is a schematic structural diagram of a semiconductor structure in accordance with an embodiment of the present disclosure.

FIG. 7 is a schematic structural diagram of a semiconductor structure in accordance with an embodiment of the present disclosure.

FIG. 8 is a schematic structural diagram of a semiconductor structure in accordance with an embodiment of the present disclosure.

FIG. 9 is another schematic structural diagram of a semiconductor structure in accordance with an embodiment of the present disclosure.

FIG. 10 is a schematic diagram of dislocation growth of a semiconductor structure in accordance with an embodiment of the present disclosure.

FIG. 11 is a schematic structural diagram of a semiconductor structure in accordance with an embodiment of the present disclosure.

### DETAILED DESCRIPTION OF THE EMBODIMENTS

Exemplary embodiments will be described in detail herein, examples of which are illustrated in the accompanying drawings. When the following description refers to the accompanying drawings, the same numerals in different accompanying drawings refer to the same or similar elements unless otherwise indicated. The embodiments described in the following exemplary embodiments are not intended to represent all embodiments consistent with the present disclosure. On the contrary, they are merely examples of apparatuses which are consistent with some aspects of the present disclosure as detailed in the appended claims.

At present, in addition to the optimization of epitaxial growth process parameters, the more effective way to solve dislocation defects is to prepare patterned SiO₂ on the substrate as a mask layer for lateral epitaxy, and epitaxial lateral overgrowth (ELO) technology is used to reduce crystal defects of GaN-based materials and to obtain high-quality GaN semiconductor materials. However, the preparation of silicon dioxide (SiO₂) mask layer on the substrate by microelectronic processing technology has complex process and high cost.

The purpose of the present disclosure is to provide a semiconductor structure that may realize a high-quality epitaxy of GaN-based materials. By enlarging a V-shaped groove during growing process of a semiconductor structure, a patterned structure without a mask may be used for lateral epitaxy of the semiconductor, therefore crystal quality of the semiconductor structure may be improved.

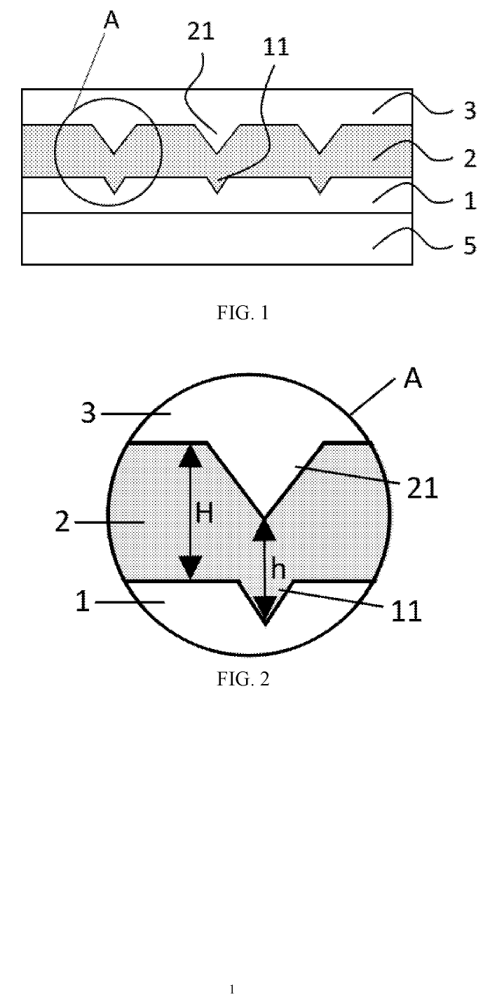

The present disclosure provides a semiconductor structure, as shown in FIG. 1, the semiconductor structure includes a substrate 5, a V-shaped groove layer 1, a V-shaped groove enlargement layer 2 and a semiconductor epitaxial layer 3 stacked from bottom to top, where a surface of the V-shaped groove layer 1 close to the V-shaped groove enlargement layer 2 has a first V-shaped groove 11. The V-shaped groove enlargement layer 2 enlarges the first V-shaped groove 11 to form a second V-shaped groove 21. The second V-shaped groove 21 is located on a surface of the V-shaped groove enlargement layer close to the semiconductor epitaxial layer 3. A size of the second V-shaped groove 21 is greater than that of the first V-shaped groove 11, and the semiconductor epitaxial layer 3 fills the second V-shaped groove 21 and is located on the V-shaped groove enlargement layer 2.

According to the semiconductor structure provided by the present disclosure, the V-shaped groove enlargement layer is secondary epitaxially grown on the V-shaped groove layer where tiny grooves formed by dislocation defects. Compared with the prior art, the present disclosure prepares the first V-shaped groove in situ by using the dislocation defects of the V-shaped groove layer material itself. The second V-shaped groove is formed by enlarging the first V-shaped groove by means of secondary epitaxy to effectively release the stress caused by lattice mismatch and thermal mismatch between the semiconductor structure and heterojunction substrate. In the secondary epitaxy. The growth orientation and growth rate different between the bottom and the side of the first V-shaped groove to realize the lateral epitaxy, which may effectively reduce the dislocation density, improve the crystal quality of the semiconductor structure, and reduce the generation of cracks of the semiconductor structure. The first V-shaped groove 11 and the second V-shaped groove 21 enlarged respectively realize a lateral epitaxy effect of the V-shaped groove enlargement layer 2 and the semiconductor epitaxial layer 3 for two times, effectively improving the crystal quality of the semiconductor epitaxial layer 3; and the first V-shaped groove 11 and the second V-shaped groove 21 are self-formed during the epitaxial growth process, so that the process of preparing patterned mask layer by traditional lateral epitaxy is omitted, which greatly reduces the preparation cost and improves the preparation efficiency.

As an optional embodiment, as shown in FIG. 2, FIG. 2 is a partial enlarged view of area A in FIG. 1. A thickness h of the V-shaped groove enlargement layer 2 inside the second V-shaped groove 21 is less than a thickness H of the V-shaped groove enlargement layer 2 outside the second V-shaped groove 21 in a vertical direction. Optionally, a ratio of the thickness h of the V-shaped groove enlargement layer inside the second V-shaped groove 21 to the thickness H of the V-shaped groove enlargement layer outside the second V-shaped groove 21 in the vertical direction is less than 0.8. In this embodiment, A size of the second V-shaped groove 21 is greater than that of the first V-shaped groove 11, where an opening width of the first V-shaped groove 11 is less than 200 nm, and an opening width of the second V-shaped groove 21 is greater than 200 nm; and a depth of the first V-shaped groove 11 is less than 200 nm and a depth of the second V-shaped groove 21 is greater than 200 nm.

The number of the second V-shaped groove 21 corresponds to the number of the first V-shaped groove 11. Optionally, a projection of the second V-shaped groove 21 on the substrate 5 corresponds to a projection of the first V-shaped groove 11 on the substrate 5 in a one-to-one relationship. Preferably, a density of the first V-shaped groove 11 is greater than 1E9/cm², which may ensure that a density of the second V-shaped groove 21 is greater than 1E9/cm². Furthermore, the second V-shaped groove 21 is located on a surface of the V-shaped groove enlargement layer 2 away from the V-shaped groove layer 1, and a patterned effect is self-formed on the V-shaped groove enlargement layer 2. When the semiconductor epitaxial layer 3 is epitaxially grown, a growth rate within the second V-shaped groove 21 is fast and laterally extended to outside of the second V-shaped groove 21, so that dislocations in the V-shaped groove enlargement layer 2 bent laterally, which greatly reduces defects in the semiconductor epitaxial layer 3, and effectively improves crystal quality of the semiconductor epitaxial layer 3.

Furthermore, a material of the V-shaped groove layer 1 is a nitride structure. Preferably, the material of the V-shaped groove layer 1 is AlN. The first V-shaped groove 11 may be self-formed by controlling conditions such as growth temperature or inject rate of Mo source during epitaxial growth of the V-shaped groove layer 1, or it may be further etched after the epitaxy growth of the V-shaped groove layer 1. In this embodiment, the first V-shaped groove 11 is preferably self-formed during epitaxial growth of the V-shaped groove layer 1, thereby simplifying preparation steps of the semiconductor structure and reducing preparation cost.

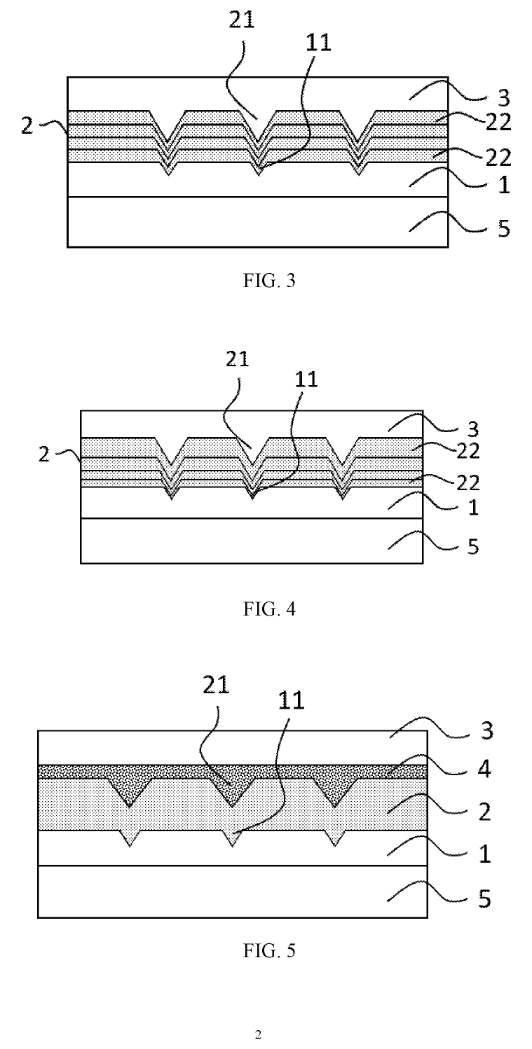

The V-shaped groove enlargement layer 2 is a multi-layer structure or a superlattice structure including one or more of AlN, AlGaN, GaN, InGaN and AlInGaN. Furthermore, FIG. 3 is another schematic structural diagram of a semiconductor structure in accordance with an embodiment of the present disclosure. As shown in FIG. 3, the V-shaped groove enlargement layer 2 includes a plurality of sub-layers 22, a surface of each of the plurality of sub-layers 22 away from the V-shaped groove layer 1 includes a second V-shaped groove 21. An opening width or an opening depth of the second V-shaped groove 21 in each of the plurality of sub-layers 22 gradually increases or increases first and then decreases, along a direction from the V-shaped groove layer 1 to the semiconductor epitaxial layer 3. In this embodiment, it is preferably that the size of the second V-shaped groove 21 in each of the plurality of sub-layers 22 gradually increases, so that the second V-shaped groove 21 formed on a surface of V-shaped groove enlargement layer 2 away from the V-shaped groove layer 1 has the largest size, and ensure a lateral epitaxial effect of the semiconductor epitaxial layer 3 and crystal quality of the semiconductor epitaxial layer 3. Optionally, the V-shaped groove enlargement layer 2 is a first superlattice structure including a plurality of periods, and the minimum repeating unit of the V-shaped groove enlargement layer 2 includes any of AlₓGa ₍₁₋ₓ₎ N/Al_{y}Ga ₍₁_{-y)} N and AlN/AlₓGa ₍₁₋ₓ₎ N/Al_{y}Ga ₍₁_{-y)} N, and x>y.

As an optional embodiment, the first superlattice structure includes a plurality of periods, each period includes at least a first period layer and a second period layer, and the second period layer is located above the first period layer. Al composition of the first period layer of the nth period is greater than Al composition of the first period layer of the (n+1)th period, and Al composition of the second period layer of the nth period is greater than Al composition of the second period layer of the (n+1)th period; or Al composition of the first period layer of the nth period is greater than Al composition of the first period layer of the (n+1)th period, and the Al composition of the second period layer of the nth period is less than Al composition of the second period layer of the (n+1)th period. In this way, the distribution of Al component in the V-shaped groove enlargement layer 2 may be further adjusted according to an actual demand to adjust the stress of the V-shaped groove enlargement layer 2, so as to reduce built-in stress of the semiconductor structure and effectively improve the crystal quality.

Materials of the substrate 5 may be Si, SiC, AlN or Al₂O₃. The substrate 5 serves as a supporting substrate of the semiconductor structure, and the V-shaped groove layer 1 is formed on the substrate 5 by epitaxy or bonding.

Material of the semiconductor epitaxial layer 3 is GaN-based material. In this embodiment, the material of the semiconductor epitaxial layer 3 is GaN.

The content of an embodiment of the present disclosure shown in FIG. 4 is approximately the same as that of an embodiment of the present disclosure shown in FIG. 1. As shown in FIG. 4, the only difference is that the thickness of each of the plurality of sub-layers 22 gradually increases along a direction from the V-shaped groove layer 1 to the semiconductor epitaxial layer 3, so that internal stress between heterogeneous materials may be gradually buffered and reduced and the crystal quality of the V-shaped enlargement layer 2 may be improved.

As an optional embodiment, Al composition of the V-shaped enlargement layer 2 gradually decreases along a direction from the V-shaped groove layer 1 to the semiconductor epitaxial layer 3; and the V-shaped groove enlargement layer includes a plurality of sub-layers 22 where Al composition of each of the plurality of sub-layers 22 gradually decreases, thereby further improving the crystal quality of the semiconductor epitaxial layer.

The content of an embodiment of the present disclosure shown in FIG. 5 is approximately the same as that of embodiments of the present disclosure shown in FIG. 1 and FIG. 4. As shown in FIG. 5, the only difference is that the semiconductor structure further includes an insertion layer 4, and the insertion layer 4 is located between the V-shaped groove enlargement layer 2 and the semiconductor epitaxial layer 3. The arrangement of the insertion layer 4 may further bent the defects in the V-shaped groove enlargement layer 2 to improve the crystal quality of the semiconductor epitaxial layer. In this embodiment, the insertion layer 4 may conformally cover the surface of the V-shaped groove enlargement layer 2 , or a flat surface of the insertion layer 4 away from the V-shaped groove enlargement layer 2 may be formed.

As an optional embodiment, the insertion layer 4 may also be located in the semiconductor epitaxial layer 3 or on a side of the semiconductor epitaxial layer 3 away from the substrate 5, which is not specifically limited in this embodiment here.

Material of the insertion layer 4 is GaN-based material including one or more of AlN, AlGaN, AlInN and AlInGaN. In this embodiment, the material of the insertion layer 4 is AlGaN.

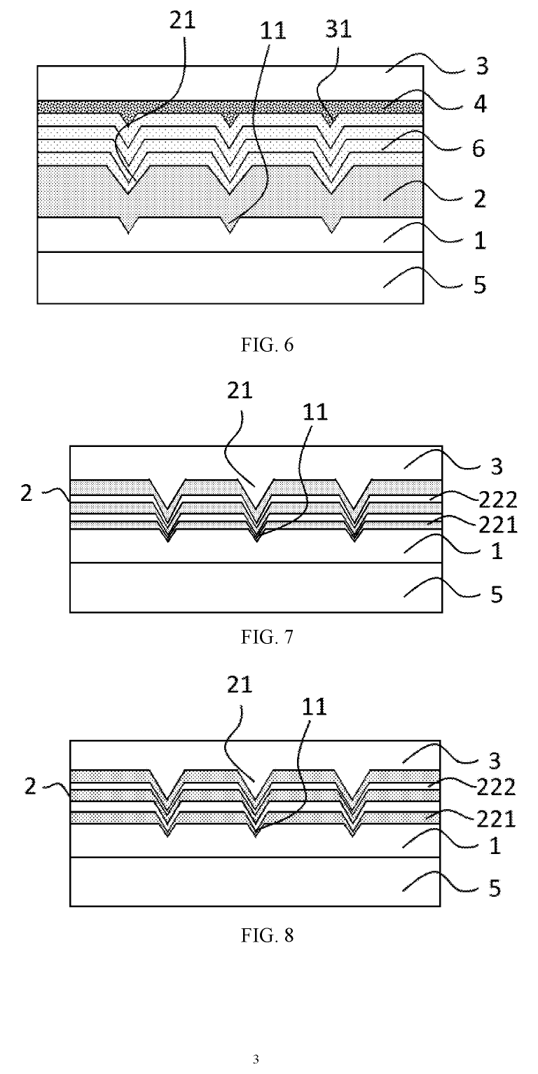

The structure of an embodiment of the present disclosure shown in FIG. 6 is approximately the same as that of any of the embodiments of the present disclosure shown in FIG. 1, FIG. 4 and FIG. 5. As shown in FIG. 6, the only difference is that the semiconductor structure also includes a second superlattice structure 6, which is adjacent to and located above the V-shaped groove enlargement layer 2. The second superlattice structure 6 includes a third V-shaped groove 31, and an opening width or an opening depth of the third V-shaped groove 31 is less than that of the second V-shaped groove 21. Furthermore, the second superlattice structure 6 includes a plurality of third V-shaped grooves 31, and an opening width or an opening depth of the plurality of third V-shaped grooves 31 gradually decreases along a direction from the substrate 5 to the semiconductor epitaxial layer 3. The second superlattice structure 6 is laterally epitaxially formed on the V-shaped groove enlargement layer 2, bending dislocations, greatly reducing defect density and improving the crystal quality. Meanwhile, a size of each of the plurality of third V-shaped groove 31 in the second superlattice structure 6 gradually decreases, so that a surface of the second superlattice structure 6 away from the substrate 5 gradually tend to be flat, which is conducive to the preparation of the subsequent epitaxial layer.

The V-shaped groove enlargement layer 2 includes a plurality of sub-layers 22, and the plurality of sub-layers include a first sub-layer and a second sub-layer that are alternately arranged.

Therein, a thickness of the first sub-layer gradually increases from bottom to top and a thickness of the second sub-layer remains unchanged, or the thickness of the first sub-layer remains unchanged, and the thickness of the second sub-layer gradually decreases; or the V-shaped groove enlargement layer 2 includes a first part and a second part, and in the first part, the thickness of the first sub-layer gradually increases from bottom to top, and the thickness of the second sub-layer remains unchanged; in the second part, the thickness of the first sub-layer remains unchanged and the thickness of the second sub-layer gradually decreases.

The first sub-layer and the second sub-layer alternated arranged are both AlN layers, or the first sub-layer is GaN layer and the second sub-layer is AlGaN layer, or the first sub-layer is AlGaN layer and the second sub-layer is AlN layer.

The structure of an embodiment of the present disclosure shown in FIG. 7 is approximately the same as that of any of the embodiments of the present disclosure shown in FIG. 1, FIG. 4, FIG. 5 and FIG. 6. As shown in FIG. 7, the only difference is that, the V-shaped groove enlargement layer 2 includes a plurality of sub-layers, and the plurality of sub-layers include a first sub-layer 221 and a second sub-layer 222 alternately arranged. A thickness of the first sub-layer 221 gradually increases from bottom to top, and a thickness of the second sub-layer 222 remains unchanged. In this embodiment, materials of the first sub-layer 221 and the second sub-layer 222 are group III nitride materials and Al component in the second sub-layer 222 is greater than that in the first sub-layer 221. Optionally, the first sub-layer 221 is a GaN layer and the second sub-layer 222 is an AlGaN layer; or the first sub-layer 221 is a GaN layer and the second sub-layer 222 is an AlN layer; or the first sub-layer 221 is an AlGaN layer and the second sub-layer 222 is an AlN layer. This arrangement makes the V-shaped groove enlargement layer 2 more conducive to enlarge the first V-shaped groove 11, the thickness of the first sub-layer 221 in the V-shaped groove enlargement layer 2 gradually increases from bottom to top. Meanwhile, Al component in the V-shaped groove enlargement layer 2 gradually decreases along a direction from the substrate 5 to the semiconductor epitaxial layer 3, which is conducive to the formation of the semiconductor epitaxial layer 3 with a high crystal quality.

In this embodiment, for the V-shaped groove enlargement layer 2, it only needs to be satisfied that the first sub-layer 221 and the second sub-layer 222 are alternately arranged. The bottom layer of the V-shaped groove enlargement layer 2 connected to the V-shaped groove layer 1 is not specifically limited, which may be the first sub-layer 221 or the second sub-layer 222.

The content of an embodiment of the present disclosure shown in FIG. 8 and is approximately the same as that of an embodiment of the present disclosure shown in FIG. 7. As shown in FIG. 8, the only difference is that, a thickness of the first sub-layer 221 in the V-shaped groove enlargement layer 2 in this embodiment remains unchanged, and a thickness of the second sub-layer 222 gradually decreases. This arrangement may make the V-shaped groove enlargement layer 2 more conducive to enlarge the first V-shaped groove 11. Meanwhile, the thickness of the second sub-layer 222 in the V-shaped groove enlargement layer 2 gradually decreases, and Al component in the V-shaped groove enlargement layer 2 gradually decreases along the direction from the substrate 5 to the semiconductor epitaxial layer 3, which is conducive to the formation of the semiconductor epitaxial layer 3 with a high crystal quality.

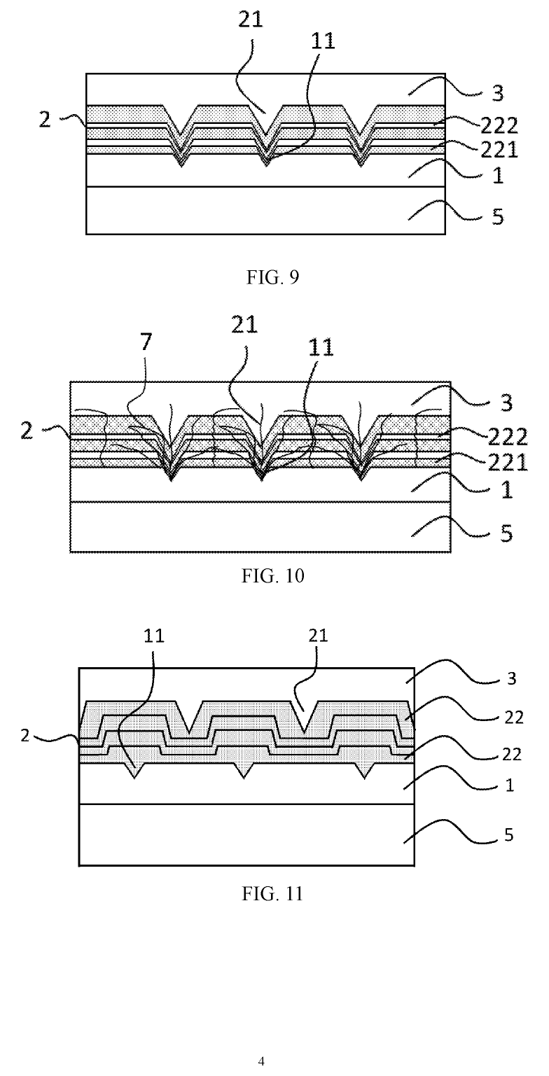

In other embodiments, as shown in FIG. 9, a thickness of the first sub-layer 221 in the V-shaped groove enlargement layer 2 gradually increases from bottom to top, and a thickness of the second sub-layer 222 gradually decreases from bottom to top to further adjust the size of the second V-shaped groove 21. Optionally, a part where the thickness of the first sub-layer 221 gradually increases from bottom to top may be not the same part where the thickness of the second sub-layer 222 gradually decreases from bottom to top, that is, the V-shaped groove enlargement layer 2 includes a first part and a second part. For example, in the first part, the thickness of the first sub-layer 221 gradually increases from bottom to top, and the thickness of the second sub-layer 222 remains unchanged. And in the second part, the thickness of the first sub-layer 221 remains unchanged, and the thickness of the second sub-layer 222 gradually decreases from bottom to top.

FIG. 10 is a schematic diagram of dislocation 7 growth of semiconductor structure in accordance with embodiment 6 of the present disclosure. As shown in FIG. 10, due to the alternating arrangement of the first sub-layer 221 and the second sub-layer 222, the growth conditions of the V-shaped groove enlargement layer 2 need to be constantly changed, and dislocation 7 generated by epitaxial growth of the V-shaped groove enlargement layer 2 on heterogeneous substrate 5 is bent and annihilated. Furthermore, since the V-shaped groove enlargement layer 2 enlarges the first V-shaped groove 11 in the V-shaped groove layer 1 to form the second V-shaped groove 21 and the semiconductor epitaxial layer 3 is formed on the V-shaped groove enlargement layer 2 by lateral epitaxy of the second V-shaped groove 21, dislocations transferred to the semiconductor epitaxial layer 3 are further bent, which greatly improves the crystal quality of the semiconductor epitaxial layer 3.

The content of an embodiment of the present disclosure shown in FIG. 11 is approximately the same as that of any of the embodiments of the present disclosure shown in FIG. 1 to FIG. 10. As shown in FIG. 11, the only difference is that, by controlling the growth conditions, the growth rate of the V-shaped groove enlargement layer 2 located on the first V-shaped groove 11 is fast, and the growth rate of the V-shaped groove enlargement layer 2 on the surface of the V-shaped groove layer 1 without the first V-shaped groove 11 is slow, resulting in a second V-shaped groove 21 is formed on the surface of the V-shaped groove enlargement layer 2 away from the substrate 5 between two adjacent first V-shaped grooves 11 correspondingly. A projection of the second V-shaped groove 21 on the substrate 5 is located between projections of the two adjacent first V-shaped grooves 11 on the substrate 5, and an opening width and depth of the second V-shaped groove 21 are greater than those of the first V-shaped groove 11. In this way, during the epitaxial growth of the semiconductor epitaxial layer 3, the growth rate of the semiconductor epitaxial layer 3 in the second V-shaped groove 21 is fast and the semiconductor epitaxial layer 3 laterally extended to the outside of the second V-shaped groove 21, so that dislocations in the V-shaped groove enlargement layer 2 may be bent laterally, which greatly reduces defects in the semiconductor epitaxial layer 3 and effectively improves the crystal quality of the semiconductor epitaxial layer 3.

The semiconductor structure provided by the present disclosure includes a substrate, a V-shaped groove layer, a V-shaped groove enlargement layer and a semiconductor epitaxial layer stacked from bottom to top on the substrate. The V-shaped groove enlargement layer enlarges tiny first V-shaped grooves on surface of the V-shaped groove layer to form the second V-shaped grooves and the V-shaped groove enlargement layer becomes a patterned structure with the second V-shaped grooves on surface, so that when the semiconductor epitaxial layer is continued to be grown, the patterned structure is helpful to realize an epitaxial lateral growth without a mask, reduce crystal defect and dislocation, and obtain a high-quality semiconductor epitaxial layer.

The first V-shaped groove and the second V-shaped groove enlarged respectively realize a lateral epitaxy effect of the V-shaped groove enlargement layer and the semiconductor epitaxial layer for two times. The lateral epitaxy for twice makes dislocation fully bend, effectively improving the crystal quality of the semiconductor epitaxy layer. Meanwhile, the first V-shaped groove and the second V-shaped groove are self-formed during the epitaxial growth process, which greatly reduces preparation cost and improves preparation efficiency.

The V-shaped groove enlargement layer is secondary epitaxially grown on the V-shaped groove layer where tiny grooves formed by dislocation defects. Compared with related art, the present disclosure prepares the first V-shaped groove in situ by using the dislocation defects of the V-shaped groove layer material itself. The second V-shaped groove is formed by enlarging the first V-shaped groove by means of secondary epitaxy to effectively release the stress caused by lattice mismatch and thermal mismatch between the semiconductor structure and heterojunction substrate. In the secondary epitaxy, the growth orientation and growth rate different between the bottom and the side of the first V-shaped groove to realize the lateral epitaxy, which may effectively reduce the dislocation density, improve the crystal quality of the semiconductor structure, and reduce the generation of cracks of the semiconductor structure.

The above descriptions are only preferred embodiments of the present disclosure, and are not intended to limit the present disclosure in any form. Although the present disclosure has been disclosed above in preferred embodiments, it is not intended to limit the present disclosure. Any person skilled in the art, without departing from the scope of the technical solution of the present disclosure, can make some changes or modifications to equivalent embodiments of equivalent changes by using the technical content disclosed above. Any simple modifications, equivalent changes and modifications made to the above embodiments according to the technical essence of the disclosure still fall within the scope of the technical solutions of the present disclosure.

What is claimed is:

1. A semiconductor structure, comprising:
a substrate;
a V-shaped groove layer, a V-shaped groove enlargement layer and a semiconductor epitaxial layer stacked from bottom to top, wherein the V-shaped groove enlargement layer is a multi-layer structure;
an insertion layer;
a first V-shaped groove, located on a surface of the V-shaped groove layer close to the V-shaped groove enlargement layer; and
a second V-shaped groove, located on a surface of the V-shaped groove enlargement layer close to the semiconductor epitaxial layer, wherein a size of the second V-shaped groove is greater than a size of the first V-shaped groove, and the semiconductor epitaxial layer fills the second V-shaped groove and is located on the V-shaped groove enlargement layer.

2. The semiconductor structure according to claim 1, wherein dislocation defects in the V-shaped groove enlargement layer are bent at the insertion layer.

3. The semiconductor structure according to claim 1, wherein the insertion layer is located between the V-shaped groove enlargement layer and the semiconductor epitaxial layer.

4. The semiconductor structure according to claim 1, wherein the insertion layer is located in the semiconductor epitaxial layer.

5. The semiconductor structure according to claim 1, wherein a surface, facing away from the V-shaped groove enlargement layer, of the insertion layer is a flat surface.

6. The semiconductor structure according to claim 1, wherein a material of the insertion layer comprises one or more of AlN, AlGaN, AlInN and AlInGaN.

7. The semiconductor structure according to claim 1, wherein a thickness of the V-shaped groove enlargement layer inside the second V-shaped groove is less than a thickness of the V-shaped groove enlargement layer outside the second V-shaped groove in a vertical direction.

8. The semiconductor structure according to claim 1, wherein an opening width of the first V-shaped groove is less than 200 nm, and an opening width of the second V-shaped groove is greater than 200 nm.

9. The semiconductor structure according to claim 1, wherein a depth of the first V-shaped groove is less than 200 nm, and a depth of the second V-shaped groove is greater than 200 nm.

10. The semiconductor structure according to claim 1, wherein a density of the first V-shaped groove and a density of the second V-shaped groove are both greater than 1E9/cm².

11. The semiconductor structure according to claim 1, wherein a projection of the second V-shaped groove on the substrate corresponds to a projection of the first V-shaped groove on the substrate in a one-to-one relationship.

12. The semiconductor structure according to claim 1, wherein the V-shaped groove enlargement layer is the multi-layer structure comprising one or more of AlN, AlGaN, GaN, InGaN and AlInGaN.

13. The semiconductor structure according to claim 1, further comprising a second superlattice structure adjacent to and located above the V-shaped groove enlargement layer, wherein the second superlattice structure comprises a third V-shaped groove corresponding to the second V-shaped groove.

14. The semiconductor structure according to claim 13, wherein an opening width of the third V-shaped groove in the second superlattice structure gradually decreases along a direction from the substrate to the semiconductor epitaxial layer.

15. The semiconductor structure according to claim 13, wherein an opening depth of the third V-shaped groove in the second superlattice structure gradually decreases along a direction from the substrate to the semiconductor epitaxial layer.
